(19) United States
(12) Patent Application Publication
(10) Pub. No.: US 2009/0046872 A1
(43) Pub. Date: Feb. 19, 2009

(54) AUTOMATIC AUDIO LEVEL CONTROL

(75) Inventor: Thomas Vollmer, Aachen (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/577,378

(22) PCT Filed: Oct. 20, 2005
(86) PCT No.: PCT/IB05/53437

§ 371 Date: Apr. 17, 2007

(30) Foreign Application Priority Data
Oct. 21, 2004 (EP) 04105225.9

(51) Int. Cl. H03G 9/00

(52) U.S. Cl. 381/102

(57) ABSTRACT

An audio signal processing device (1) is arranged for providing a level controlled output signal (Sₒ) in response to a selected input signal (Sᵢ). The device comprises a selection unit (11) for selecting an input signal (Sᵢ) from a plurality of input signals, an amplification unit (12) for amplifying the selected input signal so as to produce the output signal (Sₒ), and a gain control unit (15) for controlling the gain of the amplification unit (12) in response to a level signal (Sₗ) indicative of the audio signal level. The device is arranged for deriving the level signal (Sₗ) from the output signal (Sₒ) instead of the input signal (Sᵢ) of the amplifier (12). As a result, any signal distortions introduced by the amplifier (12) have no effect on the gain control and a greater precision is achieved.

### FIELD OF THE INVENTION

The present invention relates to an audio signal processing device for providing a level controlled output signal in response to a selected input signal, the device comprising a selection unit for selecting an input signal, an amplification unit for amplifying the selected input signal, and a gain control unit for controlling the gain of the amplification unit in dependence on an audio signal.

The present invention further relates to a method of providing a level controlled signal in response to a selected input signal.

The present invention further relates to a computer program product for carrying out the method according to the second paragraph.

### BACKGROUND OF THE INVENTION

An audio device, such as an audio amplifier or a television set, may be connected to various audio sources. In the case of an amplifier such sources may include a CD player, a DVD player, an MP3 player or a (digital or analog) cassette player, while a television set may for example have a VHS player and/or a DVD player as audio sources. It is well known that the level of the audio signals may vary between audio sources. When switching between broadcast television and a DVD player, for example, a large difference in sound levels may occur, which is very unpleasant for the user. Even between television channels differences in sound levels may be present, which typically requires the user to manually adjust the sound level.

Some television sets allow the relative gains of the audio sources to be pre-set. Although such an arrangement is useful, it suffers from the disadvantage that it is static and fails to respond to any changes of the sound level of a channel. In addition, user input is required, which some users will find troublesome.

U.S. Pat. No. 5,784,476 (Bird/Philips) discloses a multiple channel audio signal interface that includes a selector circuit, an automatic gain control unit, and an amplifier. The automatic gain control unit is constituted by an amplitude analyzer and a low-pass filter which produce a control signal that is fed to a control input of the amplifier. The amplitude analyzer is arranged for comparing the input audio signal with two pre-set threshold values and for producing a corresponding control signal, while the low-pass filter is arranged for preventing instantaneous gain changes.

This known arrangement has the drawback that the gain control is not very accurate. The gain control signal is derived from the input signal of the amplifier and does not take any distortions and/or non-linearities into account that may be introduced by the amplifier.

### OBJECT AND SUMMARY OF THE INVENTION

It is an object of the present invention to overcome these and other problems of the Prior Art and to provide an improved audio signal processing device of the type defined in the first opening paragraph and an improved method of the type defined in the second paragraph and an improved computer program product of the type defined in the third paragraph.

Accordingly, the present invention provides an audio signal processing device for providing a level controlled output signal in response to a selected input signal, the device comprising:
a selection unit for selecting an input signal from a plurality of input signals,
an amplification unit for amplifying the selected input signal so as to produce the output signal, and
a gain control unit for controlling the gain of the amplification unit in response to a level signal indicative of the audio signal level,
   wherein the device is arranged for deriving the level signal from the output signal.

By deriving the level signal from the output signal, a signal representative of the actual loudspeaker movements is used, instead of a signal that is passed through an amplifier before being fed to the loudspeaker. As a result, a more accurate gain control is achieved. In addition, a feedback arrangement is obtained, instead of a feed-forward arrangement as in the Prior Art referred to above. This also contributes to a more accurate and stable gain control.

The level signal may be the output signal itself but preferably is a signal derived from the output signal. Accordingly, the output signal may be analyzed, rectified and/or filtered in order to derive the level signal, or the output signal is fed directly to the gain control unit, in which case the gain control unit suitably processes the output signal to produce a corresponding gain control signal.

If further amplification units are present in the device or in an audio system including the device of the present invention, it is preferred that the level signal is derived from the signal nearest to the loudspeaker unit(s), but in any case downstream from the controlled amplification unit(s).

In a first embodiment, the gain control unit is coupled to the output of the amplification unit. The gain control unit may be coupled to the output of the (controlled) amplification unit directly or indirectly, indirect coupling involving an intermediate unit, such as a signal analyzer unit.

In a second embodiment, the gain control unit is coupled to a transducer arranged at a loudspeaker coupled to the device. In this embodiment, the level signal is derived from the output signal through the loudspeaker and the associated transducer. That is, the loudspeaker and the transducer convert the output signal of the (controlled) amplifier into a level signal. It is noted that the transducer may be a separately produced transducer mounted on the loudspeaker, such as an accelerometer, or an integrated transducer, such as a conductive section of the suspension of the loudspeaker.

In both embodiment described above, a gain setting unit may be arranged between the signal analyzer unit and the gain control unit. Such a gain setting unit allows the user to adjust the automatically controlled gain, and to manually set an average gain value.

The device of the present invention may further be provided with suitable filters so as to provide gain control per frequency band. Low frequencies, for example, may require less gain adjustment than medium or high frequencies.

An audio system according to the present invention comprises a device as defined above. The audio system may additionally comprise at least one loudspeaker unit, and/or at least two audio sources, such as CD players, DVD players, MP3 players, radio tuners, television tuners, etc.

The present invention also provides a method of providing a level controlled output signal in response to a selected input signal, the method comprising the steps of:
selecting an input signal from a plurality of input signals,
amplifying the selected input signal so as to produce the output signal, and
controlling the gain of the amplification unit in response to a level signal indicative of the audio signal level,
   the method further comprising the step of deriving the level signal from the output signal.

In a first embodiment, the output signal is the signal fed to a loudspeaker unit, while in a second embodiment, the output signal is the signal produced by a transducer in a loudspeaker unit. Of course the first and the second embodiment may be combined so as to use two level signals or at least a combined level signal.

The present invention additionally provides a computer program product for carrying out the method as defined above. The computer program product may comprise a computer readable set of instructions stored on a carrier medium, such as a CD (compact disc) or a DVD (digital versatile disc).

The aspects defined above and further aspects of the invention are apparent from the examples of embodiment to be described hereinafter and are explained with reference to these examples of embodiment.

### BRIEF DESCRIPTION OF THE DRAWINGS

The present invention will further be explained below with reference to exemplary embodiments illustrated in the accompanying drawings to which the invention is not limited, in which:

FIG. 1 schematically shows a multiple input audio level control device according to the Prior Art.

FIG. 2 schematically shows a first embodiment of a multiple input audio level control device according to the present invention.

FIG. 3 schematically shows a second embodiment of a multiple input audio level control device according to the present invention.

FIG. 4 schematically shows a third embodiment of a multiple input audio level control device according to the present invention.

FIG. 5 schematically shows a fourth embodiment of a multiple input audio level control device according to the present invention.

### DESCRIPTION OF EMBODIMENTS

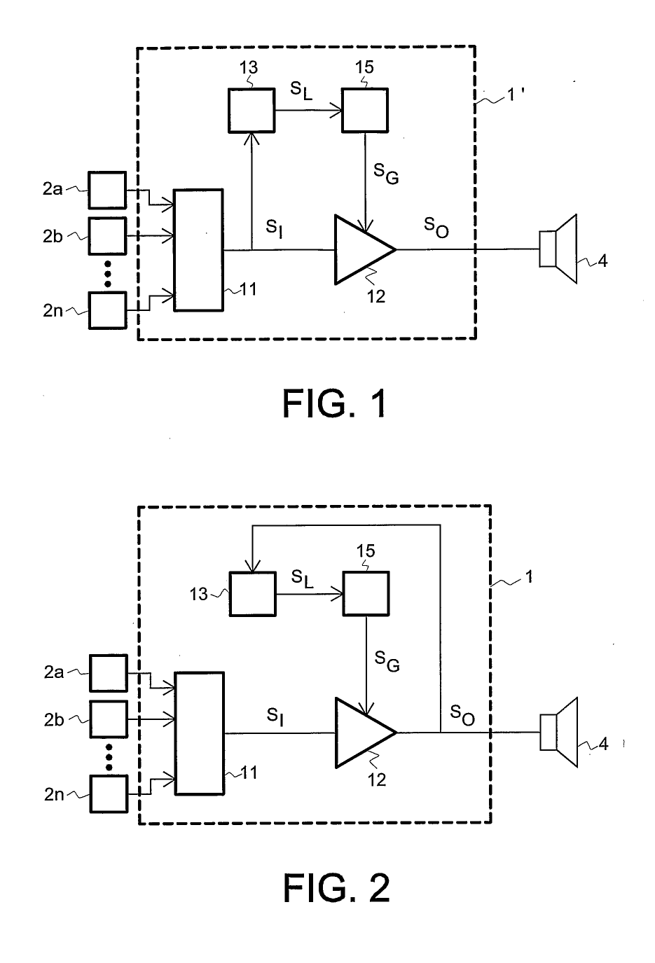

The Prior Art device 1′ shown in FIG. 1 comprises a selector unit 11, an amplifier 12, a signal analyzer 13 and a gain control unit 15. Multiple audio sources 2a, 2b, . . . , 2n are connected to the selector unit 11 which connects a selected audio source (input signal S_{I}) to the amplifier 12, which in turn is coupled to a loudspeaker unit 4.

The audio sources 2a, 2b, . . . , 2n may include a CD player, a DVD player, an MP3 player, a television set, a (digital) cassette player, a radio tuner, an Internet terminal and/or any other suitable audio source.

The amplifier 12 is a controlled amplifier, such as a VCO (voltage controlled amplifier) known per se, whose gain is controlled by a gain control signal S_{G} produced by the gain control unit 15. The gain control unit 15 derives the gain control signal S_{G} from a level signal S_{L} which represents the audio signal level and which is produced by a signal analyzer 13. In the Prior Art device shown in FIG. 1, the level signal S_{L} and the gain signal S_{G} are derived from respectively based on the input signal S_{I}.

When the selector unit 11 is operated to select another audio source, the level of the input signal S_{I} typically changes, as not all audio sound sources produce the same signal level. The change in the (average) signal level of the input signal S_{I} results in a changed level signal S_{L} and hence in a changed gain control signal S_{G}. Accordingly, a change in the level of the input signal S_{I} will typically result in a change in the gain of the amplifier 12 so as to keep the average level of the output signal S_{O} substantially unaltered.

Deriving the gain control signal S_{G} from the input signal S_{I} has the disadvantage that any distortions introduced by the amplifier 12 are not taken into account. More specifically, any non-linearities of the amplifier, or any other signal distortions, will result in an incorrect gain adjustment. As a result, the (average) level of the output signal S_{O} may still vary undesirably when another audio sound source is selected. This problem is solved by the device of the present invention.

The inventive device 1 shown merely by way of non-limiting example in FIG. 2 comprises a selector unit 11, an amplifier 12, a signal analyzer 13 and a gain control unit 15. Multiple audio sources 2a, 2b, . . . , 2n are again coupled to the selector unit 11 while a loudspeaker unit 4, which may comprise one or more loudspeakers and/or other acoustic transducers, is coupled to the amplifier 12. It is to mention all or some of the audio sources may be part of the device 1.

In contrast to the Prior Art device 1′ of FIG. 1, the level signal S_{L} is in the device 1 of FIG. 2 derived from the output signal S_{O} instead of the input signal S_{I}. As can be seen in FIG. 2, the signal analyzer 13 is coupled to the output of the amplifier 12 so as to produce a level signal S_{L} that is representative of the actual signal fed to the loudspeaker unit 4. The gain signal S_{G} is therefore related to the (average) level of the output signal S_{O}, which is the driving signal of the loudspeaker unit 4. As a result, there is a much more direct relationship between the sound produced by the loudspeaker unit and the gain signal S_{G}, and consequently a better gain adjustment is achieved.

It is noted that the signal analyzer 13 typically performs an averaging of the output signal S_{O} so as to produce a level signal S_{G} that is not unduly influenced by temporary peaks or troughs in the signal level.

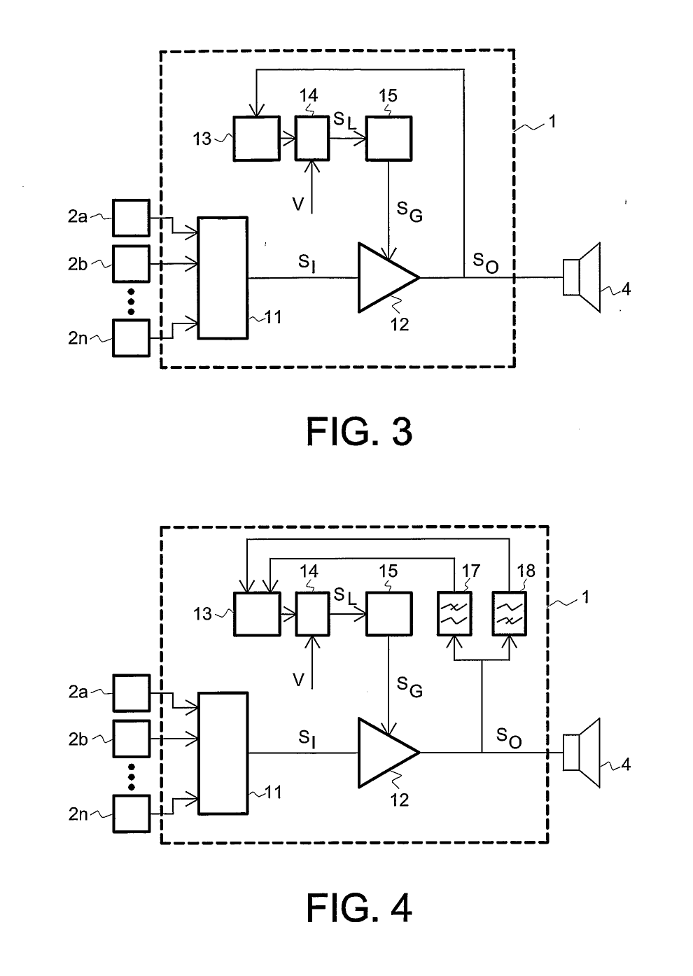

The embodiment of FIG. 3 is largely identical to the embodiment of FIG. 2, with the exception of a level setting unit 14 that is inserted between the signal analyzer 13 and the gain control unit 15. The level setting unit 14 allows the user to set the (average) gain level, on the basis of a gain setting signal V. The gain setting signal V may be derived from a variable resistor or a (remote) control unit.

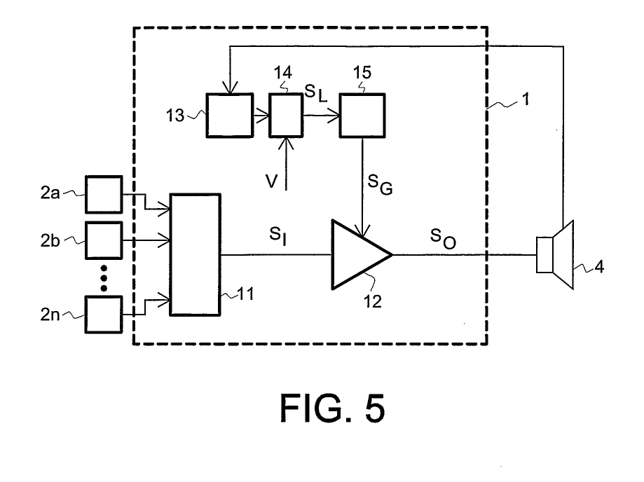

In the embodiment of FIG. 5, the signal analyzer is not coupled to the output of the amplifier 12 but to the loudspeaker unit 4 itself. In this embodiment, at least one transducer (not shown) is mounted in the loudspeaker unit 4, the transducer being coupled to the signal analyzer 13. A suitable transducer may be an accelerometer that measures the acceleration of the cone of a loudspeaker, but other transducers may also be utilized, such as a conductive section of the suspension of the loudspeaker. A measuring current may be passed through such a conductive section as to generate a measuring voltage which is substantially proportional to the excursion of the loudspeaker.

It will be understood that the gain setting unit 14 can be deleted from the embodiment of FIG. 5 without departing from the scope of the present invention. Similarly, additional components, such as a power amplifier and/or filters, may be used in many embodiments of the device of the present invention.

In the device of the present invention, the signal analyzer 13 may be constituted by a signal averager known per se, or any other suitable circuit. The analyzer 13, level setting unit 14 and gain control unit 15 could also be implemented in software by means of a digital signal processing unit (e.g. a digital signal processor, DSP), or in hardware by means of a (field) programmable gate array device (FPGA). It will be understood by those skilled in the art that a digital embodiment would require suitable D/A (digital/analog) and/or A/D (analog/digital) converters.

Accordingly, the gain control unit 15 may be constituted by an operational amplifier or a digital signal processing unit which converts the level signal S_{L} into a suitable gain control signal S_{G}.

Although the gain of amplifier 12 will typically be greater than one, in all embodiments it is possible for the gain of amplifier 12 to be smaller than 1, thus effectively causing an attenuation. A power amplifier (not shown) may be arranged between the controlled amplifier 12 and the loudspeaker unit(s) 4. Those skilled in the art will be able to modify the device 1 of FIGS. 2-4 so that it can be used for multi-channel audio, for example stereo or “5.1”.

In the embodiments shown in FIGS. 1-3 and 5, the same gain was applied to all frequencies. In further advantageous embodiments, filters may be provided to select frequency bands and to control the gain per frequency band. Low frequencies, for example, may require less gain adjustment (and a different adjustment) than higher frequencies. By providing multiple control loops for multiple frequency bands, an improved audio level control may be achieved.

This is schematically shown in FIG. 4, where two filters 17 and 18 each receive the output signal S_{O}. The filtered output signals are both fed to the signal analyzer 13. Instead of a single signal analyzer 13, multiple signal analyzers could be provided, each associated with a frequency range. It is also possible to provide separate level setting units 14 and/or gain control units 15 for each frequency range, thus obtaining an even more accurate gain control.

In the example shown in FIG. 4, the first filter 17 is a low-pass filter while the second filter 18 is a high-pass filter. This, however, is not essential and filters having substantially any pass-band may be used without departing from the scope of the present invention. Instead of two filters, three or more filters could be provided.

The embodiment of FIG. 4 has the advantage that a frequency-dependent gain control is achieved, thus allowing, for example, a greater gain adjustment for higher frequencies than for lower frequencies.

Of course the embodiments of FIGS. 4 and 5 can be combined to provide an embodiment in which at least one loudspeaker transducer is used to derive a frequency dependent gain control signal.

The present invention is based upon the insight that the actual loudspeaker signal is a better measure for gain control than the input signal.

It is noted that any terms used in this document should not be construed so as to limit the scope of the present invention. In particular, the words “comprise(s)” and “comprising” are not meant to exclude any elements not specifically stated. Single (circuit) elements may be substituted with multiple (circuit) elements or with their equivalents.

It will be understood by those skilled in the art that the present invention is not limited to the embodiments illustrated above and that many modifications and additions may be made without departing from the scope of the invention as defined in the appending claims.

1. An audio signal processing device (1) for providing a level controlled output signal (Sₒ) in response to a selected input signal (Sᵢ), the device comprising:
a selection unit (11) for selecting an input signal (Sᵢ) from a plurality of input signals,
an amplification unit (12) for amplifying the selected input signal so as to produce the output signal (Sₒ), and
a gain control unit (15) for controlling the gain of the amplification unit (12) in response to a level signal (Sₗ) indicative of the audio signal level, wherein the device is arranged for deriving the level signal (Sₗ) from the output signal (Sₒ).

2. The device according to claim 1, wherein the gain control unit (15) is coupled to the output of the amplification unit (12).

3. The device according to claim 2, wherein the gain control unit (15) is coupled to the output of the amplification unit (12) via a signal analyzer unit (13).

4. The device according to claim 1, wherein the gain control unit (15) is coupled to a transducer arranged at a loudspeaker (4) coupled to the device.

5. The device according to claim 1, wherein a gain setting unit (14) is arranged between the signal analyzer unit (13) and the gain control unit (15).

6. The device according to claim 1, further provided with filters for selecting frequency bands so as to provide frequency-dependent gain control.

7. An audio system, comprising a device (1) according to claim 1.

8. A method of providing a level controlled output signal (Sₒ) in response to a selected input signal (Sᵢ), the method comprising the steps of:
selecting an input signal (Sᵢ) from a plurality of input signals,
amplifying the selected input signal so as to produce the output signal (Sₒ), and
controlling the gain of the amplification unit (12) in response to a level signal (Sₗ) indicative of the audio signal level,
the method further comprising the step of deriving the level signal (Sᵢ) from the output signal (Sₒ).

9. The method according to claim 8, wherein the output signal (Sₒ) is the signal fed to a loudspeaker unit (4).

10. The method according to claim 8, wherein the output signal (Sₒ) is the signal produced by a transducer arranged at a loudspeaker unit (4).

11. The method according to claim 8, further comprising the step of selecting frequency bands so as to provide frequency-dependent gain control.

12. A computer program product directly loadable into the memory of a programmable device, comprising software code portions for performing the steps of a method according to claim 8 when said product is run on the device.
